(19) United States
(12) Patent Application Publication
(10) Pub. No.: US 2026/0255660 A1
(43) Pub. Date: Aug. 27, 2026

(54) VERTICAL DEVICE FORMED BY SELF-ALIGNED SEQUENTIAL PATTERNING OF TOP TRANSISTOR AND BOTTOM TRANSISTOR

(71) Applicant: Applied Materials, Inc., Santa Clara, CA (US)

(72) Inventors: Gregory Costrini, Flanders, NJ (US); Ashish Pal, San Ramon, CA (US); Benjamin Colombeau, San Jose, CA (US); El Mehdi Bazizi, San Jose, CA (US); Balasubramanian Pranatharthiharan, San Jose, CA (US)

(73) Assignee: Applied Materials, Inc., Santa Clara, CA (US)

(21) Appl. No.: 19/061,458

(22) Filed: Feb. 24, 2025

(51) Int. Cl. H10D 84/01; H10D 84/85

(52) U.S. Cl. CPC H10D 84/0188; H10D 84/0167; H10D 84/017; H10D 84/851; H10D 84/856

(57) ABSTRACT

A method may include providing a nanosheet device stack that includes a lower patterned device stack and a upper patterned device stack, disposed above the lower patterned device stack, where the lower patterned device stack is disposed on a substrate base. The method may further include forming a lower dummy gate layer around the lower patterned device stack, and forming a upper dummy gate layer around the upper patterned device stack. The method may also include patterning the upper dummy gate layer to form a upper dummy gate around the upper patterned device stack, wherein an upper gate slot is formed. The method may also include patterning the lower dummy gate layer using the upper gate slot, wherein a gate slot is formed that extends through the lower patterned device stack and the upper patterned device stack.

### FIELD OF THE DISCLOSURE

The present embodiments relate to semiconductor device patterning, and more particularly, to devices and techniques for forming vertically stacked devices where a first transistor is formed over a second transistor.

### BACKGROUND OF THE DISCLOSURE

As integrated circuit (IC) technologies progress towards smaller technology nodes, multi-gate devices have been used to improve gate control by increasing gate- channel coupling, reducing off-state current, and reducing short-channel effects (SCEs). Gate-all-around (GAA) transistors, are examples of devices that provide high performance and low leakage applications. The channel region of GAA transistors may be formed from nanowires, nanosheets (NS), or other nanostructures.

One recent innovation for device fabrication is to form a device that incorporates the function of a known N-type field effect transistor (NFET) and a known P-type field effect transistor (PFET) in a vertical stacked structure that arranges the NFET and PFET in a single stack. This device may be referred to as a complementary field effect transistor (CFET) and may provide similar functionality as a known so-called CMOS device. In known CMOS type devices, whether arranged as planar devices, Fin type devices (FinFEt), planar GAA devices, the PFET device may be arranged generally in a co-planar fashion with the NFET. In the CFET device, the final structure arranges a given PFET directly over or directly under an NFET. Each of the PFET and NFET devices in turn, may be formed from a nanosheet process that results in a gate-all-around structure for the PFET and NFET. While this architecture in principle provides increased performance and reduced power consumption compared to planar counterparts, formation of CFET devices entails several process challenges due to the increased complexity and verticality of such devices.

Accordingly, improved approaches are needed for forming vertical stacked devices, such as CFET devices.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one embodiment, a method is provided. The method may include providing a nanosheet device stack that includes a lower patterned device stack and a upper patterned device stack, disposed above the lower patterned device stack, where the lower patterned device stack is disposed on a substrate base. The method may further include forming a lower dummy gate layer around the lower patterned device stack, and forming a upper dummy gate layer around the upper patterned device stack. The method may also include patterning the upper dummy gate layer to form a upper dummy gate around the upper patterned device stack, wherein an upper gate slot is formed. The method may also include patterning the lower dummy gate layer using the upper gate slot, wherein a gate slot is formed that extends through the lower patterned device stack and the upper patterned device stack.

In another aspect, a method of forming a complementary field effect transistor is provided. The method may include providing a nanosheet device stack that includes a lower patterned device stack and a upper patterned device stack, disposed on the lower patterned device stack, where the lower patterned device stack is disposed on a substrate base. The method may also include forming a lower dummy gate layer around the lower patterned device stack, forming an insulator layer on the lower dummy gate layer, and forming a upper dummy gate layer on the insulator layer, where the upper dummy gate layer further extends around the upper patterned device stack. The method may further include etching the upper dummy gate layer to form a upper dummy gate around the upper patterned device stack, wherein an upper gate slot is formed, and etching the lower dummy gate layer using the upper gate slot, where a gate slot is form that extends through the upper patterned device stack and the lower patterned device stack.

### BRIEF DESCRIPTION OF THE DRAWINGS

The accompanying drawings illustrate exemplary approaches of the disclosure, including the practical application of the principles thereof, as follows:

FIGS. 1A-1AF illustrates a perspective cross-sectional view of an exemplary device at various stages of formation, according to embodiments of the present disclosure;

FIG. 2 presents a process flow, according to embodiments of the disclosure; and

FIG. 3 presents another process flow, according to embodiments of the disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of "slices", or "near-sighted" cross-sectional views, omitting certain background lines otherwise visible in a "true" cross-sectional view, for illustrative clarity. Furthermore, for clarity, some reference numbers may be omitted in certain drawings.

### DETAILED DESCRIPTION

Methods, and devices in accordance with the present disclosure will now be described more fully hereinafter with reference to the accompanying drawings, where various embodiments are shown. The methods, and devices may be embodied in many different forms and are not to be construed as being limited to the embodiments set forth herein. Instead, these embodiments are provided so the disclosure will be thorough and complete, and will fully convey the scope of the methods to those skilled in the art.

For the sake of convenience and clarity, terms such as "top," "bottom," "upper," "lower," "vertical," "horizontal," "lateral," and "longitudinal" will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word "a" or "an" is to be understood as including plural elements or operations, until such exclusion is explicitly recited. Furthermore, references to "one embodiment" of the present disclosure are not intended as limiting. Additional embodiments may also incorporate the recited features.

Furthermore, the terms "substantial" or "substantially," as well as the terms "approximate" or "approximately," can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed "on," "over" or "atop" another element, the element can be directly on the other element or intervening elements may also be present. In contrast, when an element is referred to as being "directly on," "directly over" or "directly atop" another element, no intervening elements are present.

Embodiments described herein are directed to formation of vertically stacked devices that include two different transistor types, such as NFETs and PFETs. The devices disclosed herein may be based upon gate-all-around (GAA) transistors that are formed from a nanosheet structure, based upon epitaxially grown superlattice structures. Non-limiting examples of nanosheet structures include a superlattice of monocrystalline silicon layers that alternated with monocrystalline silicon:germanium alloy (SiGe) layers. The Ge content of the SiGe layers may be such that the SiGe layers may be readily selectively etched with respect to the silicon layers.

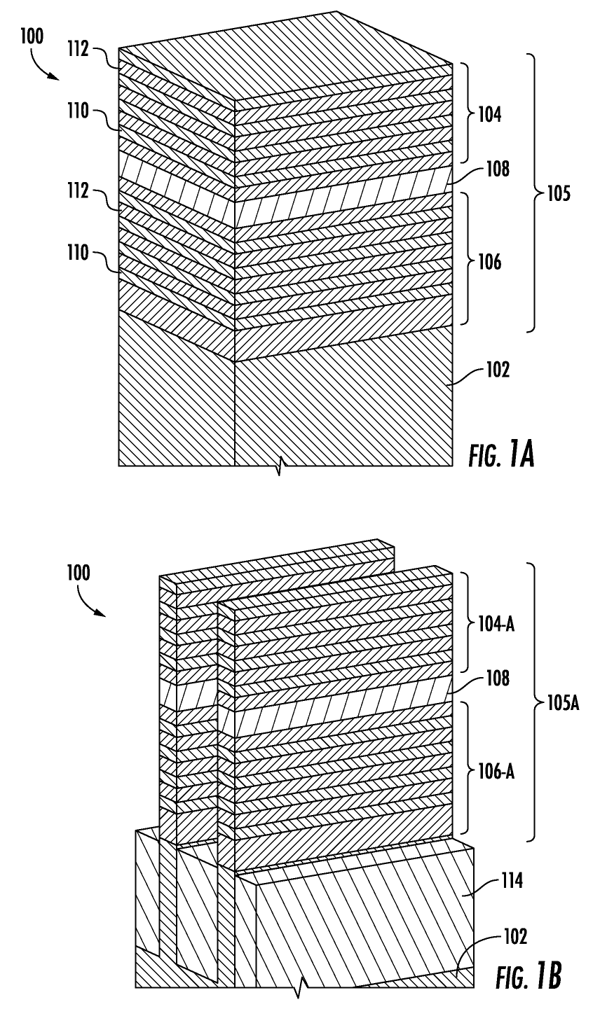

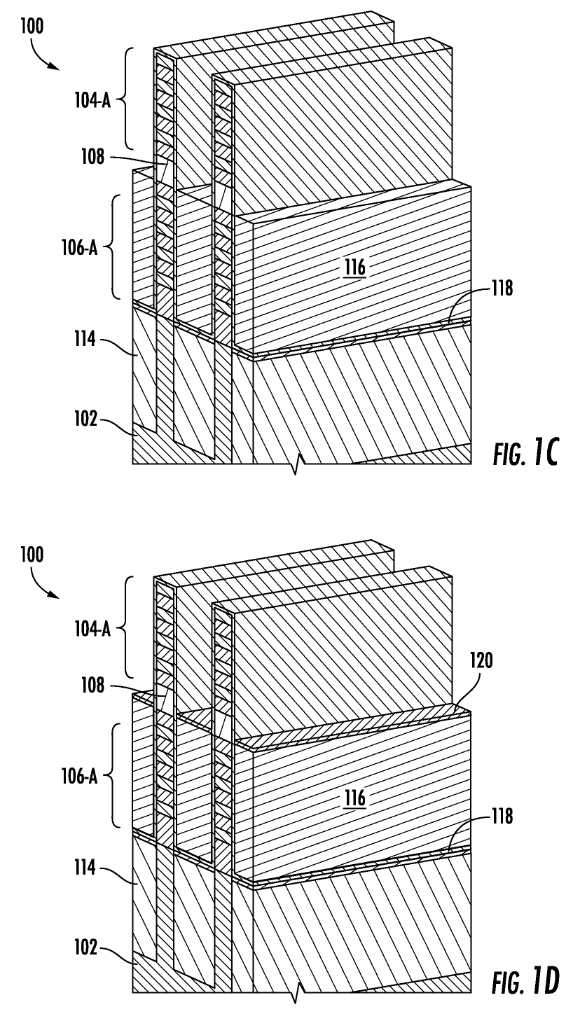

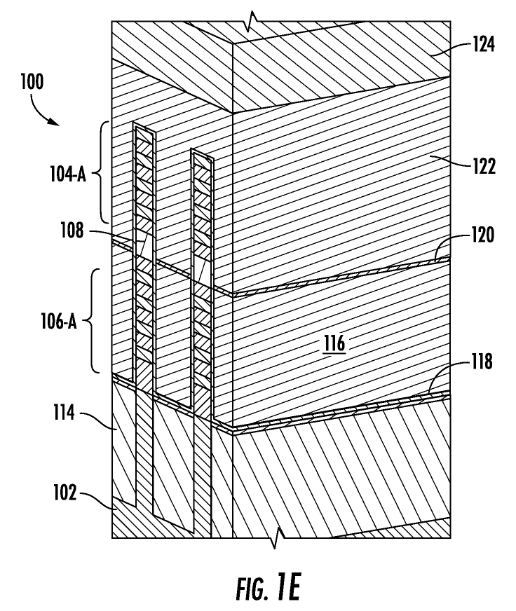

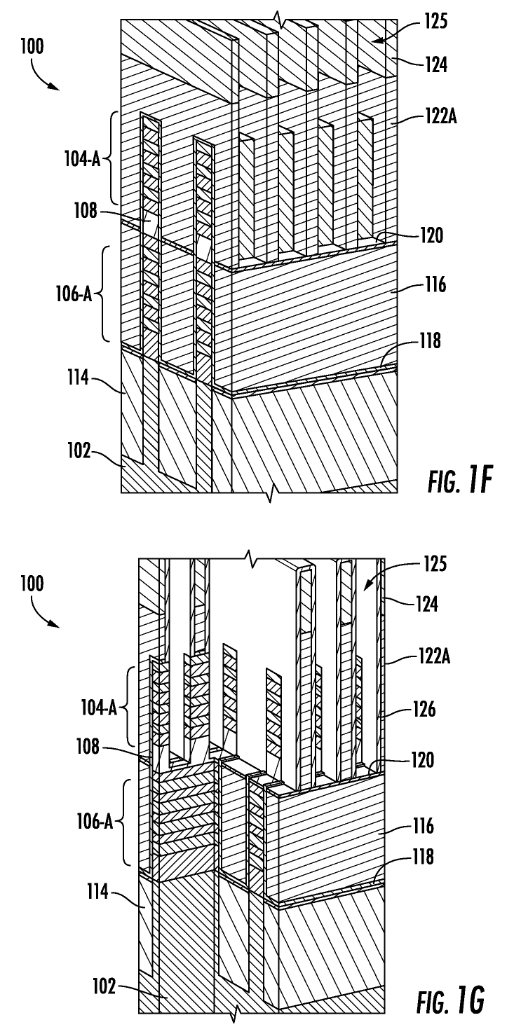

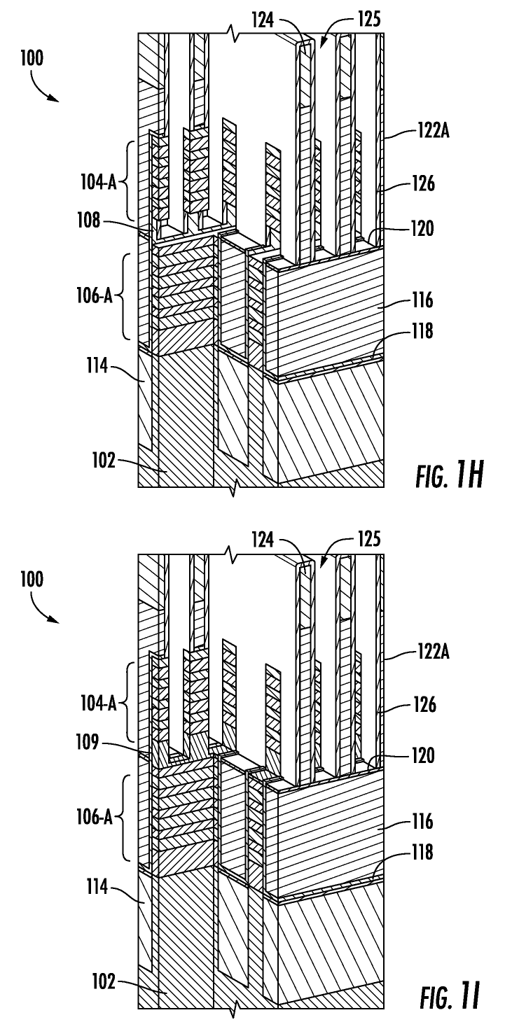

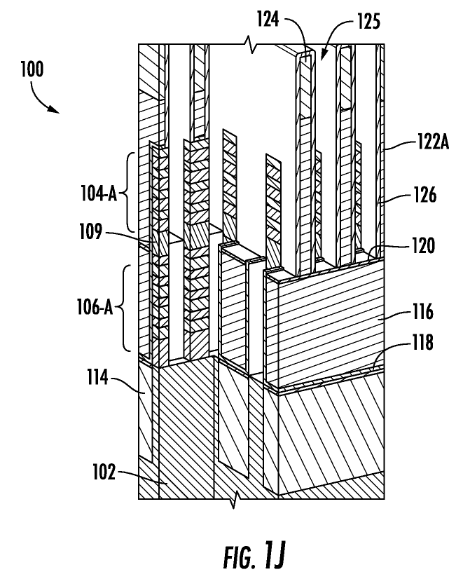

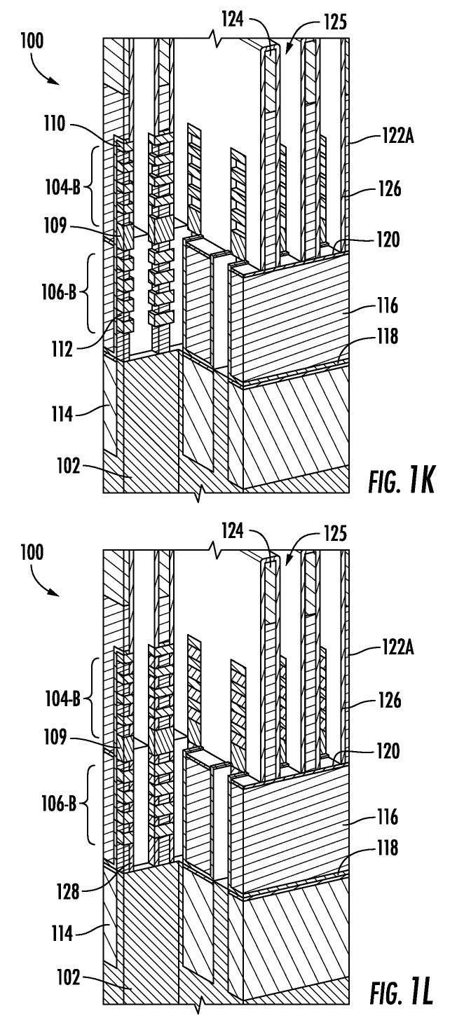

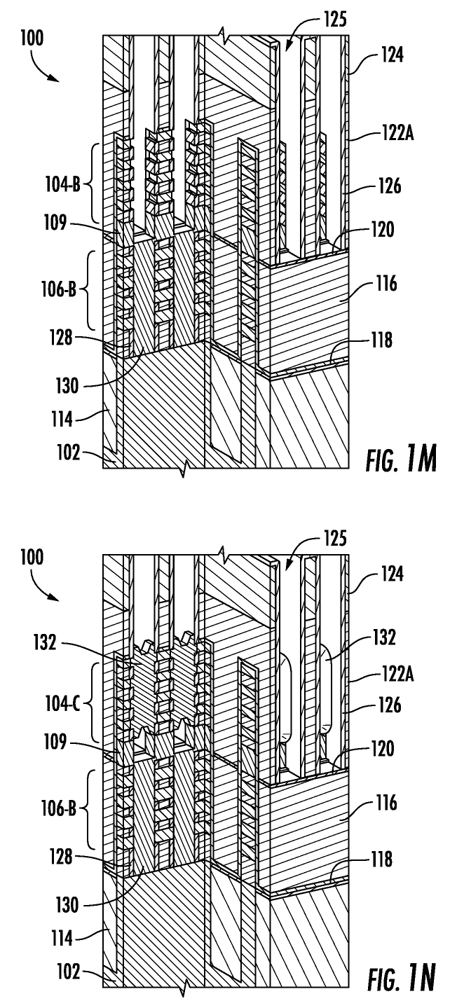

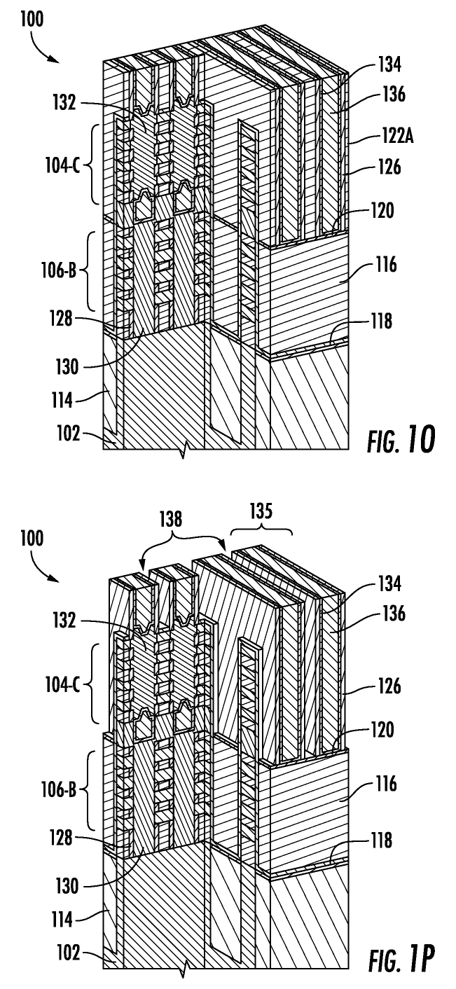

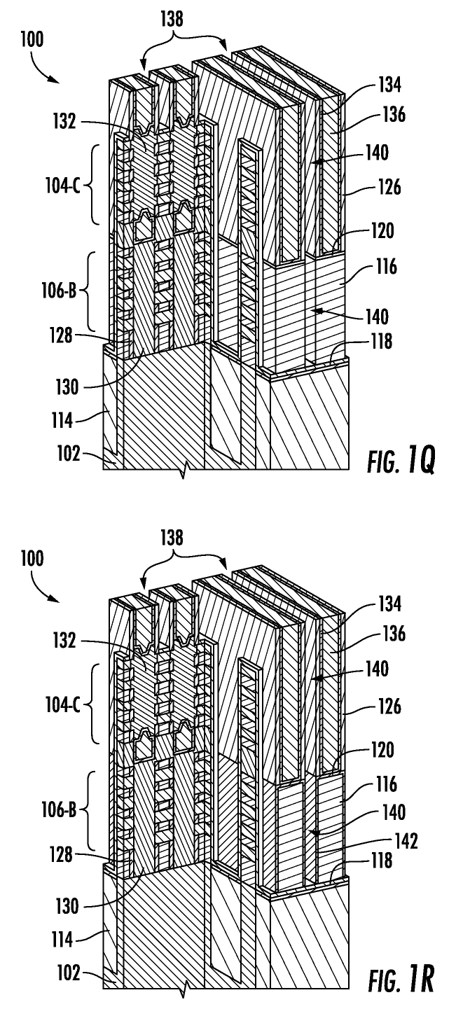

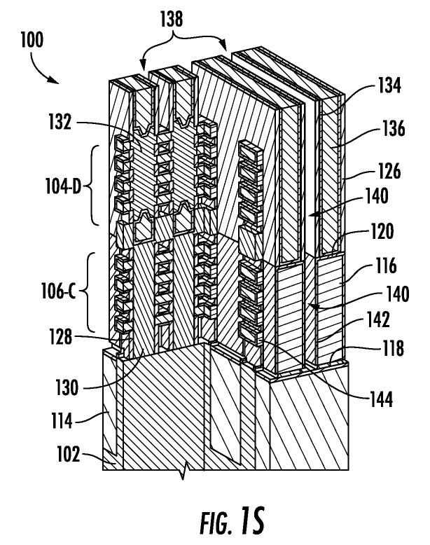

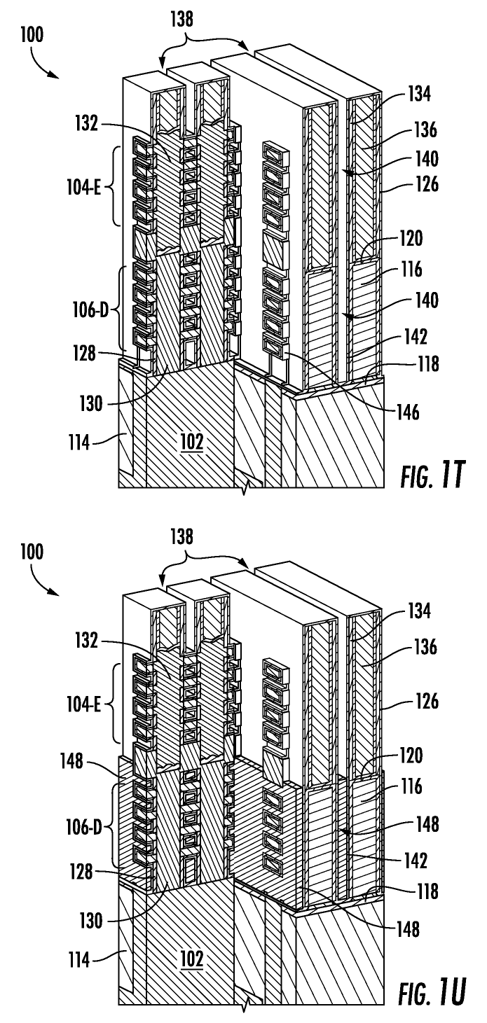

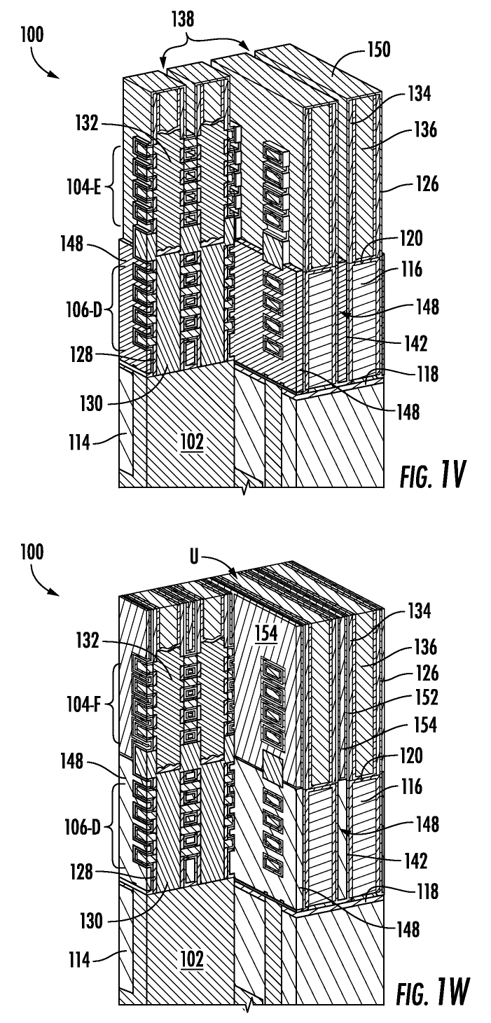

With reference to FIGS. 1A-1AF, an approach for forming a semiconductor device (hereinafter "device") 100 according to one or more embodiments will be described. At FIG. 1AF, the device 100 is shown at a stage of formation after formation of individual PFET and NFET transistors.

Turning to FIG. 1A, there is shown an early stage of device formation, where a nanosheet stack 105 is provided on a substrate base 102. As used herein, the substrate base 102 may be silicon, such as a silicon wafer. Alternatively, or additionally, substrate base 102 may includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AIGaAs, GalnAs, GaInP, and/or GaInAsP; or combinations thereof. Alternatively, substrate base 102 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods. The substrate base 102 can include various doped regions depending on design requirements of the device 100. For example, the substrate base 102 may include p-type doped regions configured for n-type GAA transistors and n-type doped regions configured for p-type GAA transistors. P-type doped regions are doped with p-type dopants, such as boron, indium, other p-type dopant, or combinations thereof. N-type doped regions are doped with n-type dopants, such as phosphorus, arsenic, other n-type dopant, or combinations thereof. In some implementations, the substrate base 102 includes doped regions formed with a combination of p-type dopants and n-type dopants.

The nanosheet stack 105 may include a lower device stack 106, an upper device stack 104, and a separator layer 108, disposed between the lower device stack 106 and the upper device stack 104. The lower device stack 106 and the upper device stack 104 may be formed by known processes. The upper device stack 104 and the lower device stack 106 of the nanosheet stack 105 are characterized by an alternating sequence of first layers 110 and second layers 112 that may be grown epitaxially one upon the other. In one example, the first layers 110 may be monocrystalline silicon and the second layers may be monocrystalline silicon: germanium alloy of suitable composition.

Turning to FIG. 1B, there is shown a subsequent stage of device formation, where the nanosheet stack 105 has been patterned to form a patterned device stack 1 OSA. the patterning may be accomplished by suitable known lithographic processes and by reactive ion etching (RIE) to form a lower patterned device stack 106-A and a upper patterned device stack 104A, disposed above the lower patterned device stack 106A. The substrate base 102, which base may be monocrystalline silicon, has also been etched, and a shallow trench isolation (STI) layer 114 has been formed at a lower position, below the lower patterned device stack 106A, and separating adjacent individual ones of the patterned device stack 1OSA.

Turning to FIG. 1C, there is shown a subsequent stage of device formation where a lower dummy gate layer 116 has been formed around the lower patterned device stack 106A. In one embodiment, the lower dummy gate layer 116 may be polyerystalline silicon. In one embodiment, the formation of the lower dummy gate layer 116 may take place by depositing a dummy gate layer, such as a polysilicon layer, performing a polishing operation, such as chemical mechanical polishing (CMP), and performing a recess operation. As such, the lower dummy gate layer 116 does not extend above the separator layer 108. A layer 118 may be provided between the STI layer 114 and the lower dummy gate layer 116, where in some embodiments the layer 118 may include an etch stop layer.

Turning to FIG. 1D, there is shown a subsequent stage of device formation where an insulator layer 120 has been formed on the lower dummy gate layer 116. The insulator layer 120 may be formed, for example, by oxidation or nitridation of a polysilicon layer that forms the lower dummy gate layer 116.

Turning to FIG. 1E, there is shown a subsequent stage of device formation where an upper dummy gate layer 122 has been formed around the upper patterned device stack 104A. Note that the upper dummy gate layer 122 may be formed by deposition of an upper dummy gate layer, such as polysilicon, followed hy CMP and deposition of a mask layer 124, such as a known hardmask layer or hardmask material.

Turning to FIG. 1F, there is shown a subsequent stage of device formation where the upper dummy gate layer 122 has been patterned to form an upper dummy gate 122A around the upper patterned device stack 104A, where an upper source/drain slot 125 is formed. The upper source/drain slot 125 is formed between adjacent ones of the upper dummy gate 122A. In some embodiments, the upper dummy gate 122A may be formed by using lithography and RIE to etch the mask layer 124 and upper dummy gate layer 122, where etching terminates at the insulator layer 120. Thus, the lower dummy gate layer 116 is not etched.

Turning to FIG. 1G, there is shown a subsequent stage of device formation, after a sacrificial oxide etch has been performed, and after a spacer layer 126 has been deposited, and after reactive ion etching subsequent to the spacer deposition. Moreover, a source/drain etch has been performed to remove semiconductor material of the upper patterned device stack 104A in the upper source/drain slot 125.

Turning to FIG. 1H there is shown a subsequent stage of device formation after a selective etch has been performed to remove a portion of the separator layer 108, which layer may be a SiGe40% alloy. Turning to FIG. 1I there is shown a subsequent stage of device formation after deposition of a middle dielectric insulator layer 109 and RIE has been performed to isolate the upper patterned device stack 104-A, from the lower patterned device stack 106-A.

The depicted process flow for forming a middle dielectric insulator layer 109 at the instance of FIG. 1I is expected to improve a subsequent fill process to take place, since there is a lower surface that will aid in a bottom up type of fill process. In contrast, if the dummy gate is etched over the bottom device also, then a middle dielectric insulator (MDI) opening is in the middle of the gate, so that the MDI fill process is restricted to a conformal deposition. Such a conformal deposition increases the difficulty for filling the dimensions of the MDI without pinching off a gate slot. In addition, the embedded etch stops in the polysilicon gate may provide better process tolerance for subsequent metal gate formation and allow a reduction of the MDI height, which circumstance will also ease the fill process.

Turning to FIG. 1J there is shown a subsequent stage of device formation after source/drain recess has been performed to remove semiconductor material of the lower patterned device stack 106-A. Turning to FIG. 1K there is shown a subsequent stage of device formation where the second layers 112 of the nanosheet stack 105 have been selectively etched. According to embodiments where the second layers 112 are formed of a silicon:germanium (SiGe) alloy, a suitable selective etch that selectively etches SiGe with respect to Si is performed. The upper device stack is now represented as recessed upper device stack 104-B, while the lower device stack is represented as recessed lower device stack 106-B.

Turning to FIG. 1L there is shown a subsequent stage of device formation where an inner spacer 128 has been formed. Note the inner spacer is formed in the second layers 112.

Turning now to FIG. 1M, there is shown a subsequent stage of device formation where a dielectric cover layer 130 has been applied to the recessed lower device stack 106- B. In this manner, the source/drain region of the recessed lower device stack 106 is protected from unwanted processing. The dielectric cover layer be 130 formed by deposition of a dielectric material, followed by a recess operation. The top of the dielectric cover layer 130 extends to the level of the insulator layer 120 at this stage, thus covering the semiconductor regions of the recessed lower device stack 106.

Turning now to FIG. 1N there is shown a subsequent stage of device formation where an epitaxial portion 132 has been grown in the upper source/drain slot 125. The epitaxial portion 132 will form epitaxially with respect to exposed regions of the first layers 110 in the upper source/drain slot 125. The recessed upper device stack is now represented as regrown upper device stack 104-C.

Subsequently, the upper source/drain slot 125 may be filled and the upper dummy gate 122A may be removed. Turning to FIG. 10 there is shown a subsequent stage of device formation where a contact etch stop layer (CESL) liner 134 has been formed, middle-of-the-line (MOL) dielectric deposition performed, and a CMP operation completed so that a dielectric fill 136 is disposed in the location of the former place of the upper source/drain slot 125.

Turning to FIG. 1P there is shown a subsequent stage of device processing where the dummy gate 122A has been selectively removed, leaving in place a set of pillars 135, each of pillars 135 being defined by a combination the dielectric fill 136, the CESL liner 134 and spacer layer 126. For example, if the dummy gate 112A is formed of polysilicon a selective etch may be performed to selectively etch polysilicon with respect to material of the CESL liner 134 and spacer layer 126 and dielectric fill 136. Thus, an upper gate slot 138 is formed between adjacent ones of the pillars 135.

Turning to FIG. 1Q there is shown a subsequent stage of device formation after the patterning of the lower dummy gate layer 116 using the upper gate slot 138. As such, a gate slot 140 is formed that extends through the lower patterned device stack and the upper patterned device stack. Note that the gate slot 140 is thus formed in a manner that a lower portion of the gate slot 140 adjacent the lower device stack 106 is self-aligned with the upper portion of the gate slot 140 adjacent to the upper device stack 104. In the example of polysilicon, the lower dummy gate layer 116 may be selectively removed by a suitable RIE process, for example.

Turning to FIG. 1R, there is shown a subsequent stage of device processing where a lower device spacer 142 has been formed adjacent to the sidewalls of remaining portions of the lower dummy gate layer 116. In the case of polysilicon material for lower dummy gate layer 116, the lower device spacer 142 may be formed by oxidation or nitridation of the exposed polysilicon sidewalls.

Turning to FIG. 1S, there is shown a subsequent stage of device processing after removal of a sacrificial oxide layer and selective etching of the second layers 112 in the gate slots 140. For example, where the second layers 112 are formed of SiGe, the SiGe may be selectively removed from the region of the upper device stack 104 and lower device stack 106, leaving cavities that surround first layers 110 in the gate slots 140. These device stacks, with removal of second layers 112, are represented as upper device stack 104D and lower device stack 106-C, respectively. An interface oxide layer 144 may then be formed on the exposed portions of first layers 110.

This layer results from a low temperature chemical oxidation of the channel silicon to form an interface layer on the silicon channel. As such, the interface oxide layer 144 represents an interface layer between the channel silicon and a high K dielectric (such as HfOx) to be formed. The interface oxide layer 144 may be grown to a suitable thickness, such as between 5 A and 10 A, and in particular, approximately 8 A, and is required to minimize gate leakage.

Turning to FIG. 1T, there is shown a subsequent stage of device processing after formation of a high dielectric constant (high-K) layer is formed in the gate slot 140 on the lower patterned device stack and the upper patterned gate stack. In particular, a material such as HfO2 may be deposited by atomic layer deposition to coat exposed portions in the gate slot 140 including exposed portions of the first layers 110. The high- K layer is shown as layer 146, and may thus coat the channel regions of transistor devices to be formed. Note that the layer 146 is formed simultaneously on the upper patterned device stack, now shown as device stack 104-E, as well as lower patterned device stack, now shown as device stack 106D.

To facilitate separate completion of a transistor from the device stack 104-E, the lower portion of the gate slot 140 may be provided with a filler in order to protect device structures in the device stack 106D. Turning to FIG. 1U, there is shown a subsequent stage of device processing where the gate slot 140 is filled adjacent to the device stack 106D. A fill material 148 such as TiN may be used as a placeholder material for this purpose.

Turning to FIG. 1V, there is shown a subsequent stage of device processing where a drive in annealing process has been performed to adjust work function of the high- K layer, layer 146. In addition, liner metals have been stripped from the device stack 104- E.

Turning to FIG. 1W, there is shown a subsequent stage of device processing where a work function metal 152 has been deposited around the exposed portions of first layers 110, followed by deposition of a metal fill layer 154 that now fills the upper part of gate slot 140. The metallized device stack is now shown as device stack 104-F. The top of the device 100 may also be planarized(forming a planarized upper surface (U)), such as by CMP at this stage. Note that the formation of a transistor device from the device stack 104-F is now nearly complete.

Turning to FIG. 1X there is shown a subsequent stage of device processing. At this stage, the planarized upper surface (U) of the original state of device 100 has been bonded to a carrier substrate, shown as carrier wafer 156, such as a silicon wafer. In the view of FIG. 1X, the device 100 has been rotated so that the planarized upper surface U is now located in the lower part of the image. In addition, the substrate base 102 and the STI layer 114 have been removed, exposing the device stack 104D.

Turning to FIG. 1Y there is shown a subsequent stage of device processing. At this stage, the dielectric layer over source/drain regions of the device stack 106-D has been removed.

Turning to FIG. 1Z, there is shown a subsequent stage of device processing where sacrificial oxide and the lower dummy gate layer 116 have been selectively removed, forming a lower source/drain slot 155.

Turning to FIG. 1AA, there is shown a subsequent stage of device processing an epitaxial layer 157 is grown on the exposed surfaces of the second layers 112 in the lower source/drain slot 155, forming the device stack 106E. Turning to FIG. lAB there is shown a subsequent stage of device formation where a CESL liner 158 has been formed, MOL dielectric deposition performed, and a CMP operation completed so that a dielectric fill 160 is disposed in the location of the former place of the lower source/drain slot 155.

Turning to FIG. 1AB there is shown a subsequent stage of device formation where a CESL liner 158 has been formed, MOL dielectric deposition performed, and a CMP operation completed so that a dielectric fill 160 is disposed in the location of the former place of the lower source/drain slot 155.

Turning to FIG. 1AC there is shown a subsequent stage of device formation where the fill material 148 has been selectively removed, forming a lower gate slot 159. Note that the lower gate slot 159 may be considered to be a restoration of the gate slot 140, in that the lower gate slot 159 is located at the region of the original lower portion of the gate slot 140.

Turning to FIG. 1AD there is shown a subsequent stage of device formation where a drive in annealing process has been performed to adjust work function of the high- K layer, layer 146. In addition, liner metals have been stripped from the device stack device stack 106E.

Turning to FIG. 1AE, there is shown a subsequent stage of device processing where a work function metal 162 has been deposited around the exposed portions of first layers 110, followed by deposition of a metal fill layer 164 that now fills the originally lower part of gate slot 140. The metallized device stack is now shown as device stack 106- F. The outer surface of the device 100 may also be planarized, such as by CMP at this stage. Note that the formation of a transistor device from the device stack 104-F is now nearly complete.

Turning to FIG. 1AF, there is shown a subsequent stage of device processing where a contact 166 has been formed for device stack 106-F forming the transistor 106-G. The contact 168 for device stack 104-F is subsequently formed, following a second carrier bonding and removal of the first carrier wafer to expose the device stack 104-F from the top. These process steps are not depicted herein. In this fashion, the contact formation is made to the top and bottom devices, separately and avoids high-aspect contact geometries. Furthermore, the contacts are formed prior to the back-end-of-line (BEOL) metal wiring formation, which process will not withstand the thermal budget of the contact formation process.

Note that the transistor 104-G and transistor 106-G will be formed such that the two transistors have opposite polarity, thus forming a complementary field effect transistor.

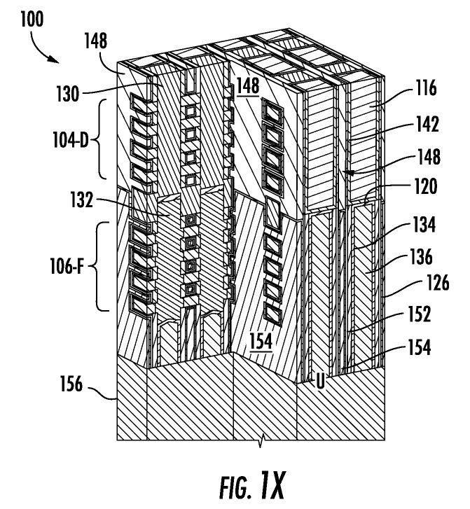

FIG. 2 presents a process flow 200, according to embodiments of the disclosure. At block 202, a device substrate is provided that includes a nanosheet device stack, disposed on a substrate base. In some embodiments, the nanosheet device stack may be made of a superlattice of alternating device layers and sacrificial layers. In particular embodiments, the nanosheet device stack may be made of a superlattice of alternating silicon and SiGe layers according to some embodiments. The nanosheet device stack may be divided into a lower device stack and an upper patterned device stack, disposed above the lower device stack, where the lower patterned device stack is disposed on the substrate base.

At block 204, the nanosheet device stack is patterned to form a patterned nanosheet device stack that includes an upper patterned device stack, disposed over a lower patterned device stack. The patterning may take place according to known lithographic and etching processes.

At block 206, a lower dummy gate layer is formed around the lower patterned device stack. In some embodiments, the lower dummy gate may be formed by deposition of polysilicon on the patterned nanosheet device stack, followed by recess etching so that the lower dummy gate layer extends adjacent to the lower patterned device stack, but not next to the upper patterned device stack.

At block 208, an insulator layer is formed on an upper surface of the lower dummy gate layer. The insulator layer may be formed by oxidation or nitridation of a polysilicon material, for example.

At block 210, an upper dummy gate layer is formed over the lower dummy gate and insulator layer.

At block 212, an upper patterned dummy gate is formed by etching the upper dummy gate layer. The patterning may take place according to known lithographic and etching processes. The patterning may take place so that just the upper dummy gate layer is etched and the subjacent lower dummy gate layer is not etched. The patterning may be performed so as to form a plurality of dummy gate structures that are separated by upper source/drain slots.

At block 214, epitaxial portions are grown adjacent to the nanosheets of the patterned upper device stack within the upper source/drain slots.

At block 216, the upper source/drain slots are filled. The filling of the upper source/drain slots may include forming a contact etch stop liner before deposition of a dielectric material and chemical mechanical polishing to planarize the patterned upper device stack.

At block 218, the upper dummy gate material is selectively removed between adjacent filled upper source/drain slots. The selective removal may take place by etching such that the etching process terminates on the insulator layer that is disposed between the upper patterned dummy gate and the lower dummy gate layer. As such, a plurality of pillars are defined from the dielectric material that was used to fill the upper source/drain slots. Moreover, a set of upper gate slots are formed in regions between adjacent pillars.

At block 220, the lower dummy gate layer is selectively removed below the upper gate slots. As such, a gate slot is formed that extends through the lower patterned device stack and the upper patterned device stack.

At block 222, the sacrificial layers of the lower patterned device stack and the upper patterned device stack are selectively removed. In examples where the sacrificial layers are SiGe, these layers may be removed by selective etching to leave a series of Si device layers in place in the upper patterned device stack and the lower patterned device stack.

At block 224, a high-K layer is deposited over the surface of the Si device layers. At block 226, the lower part of the gate slot, adjacent to the lower patterned device stack is filled with a placeholder material, such as TiN.

At block 226, the device layers are metallized with a gate metal in the upper part of the gate slot, forming a first transistor.

At block 228, the upper surface of the upper patterned device stack is bonded to a carrier wafer and the substrate base is removed from the lower surface of the lower patterned device stack.

At block 230, the lower dummy gate layer is selectively removed from the lower patterned device stack to form a set of lower source/drain slots. At block 232, epitaxial portions are grown adjacent to the lower patterned device stack layers in the lower source/drain slots.

At block 234, the lower source/drain slots are filled. At block 236, the placeholder metal is removed from the lower part of the gate slot. At block 238, the device layers in the lower part of the gate slot are metallized, forming a second transistor.

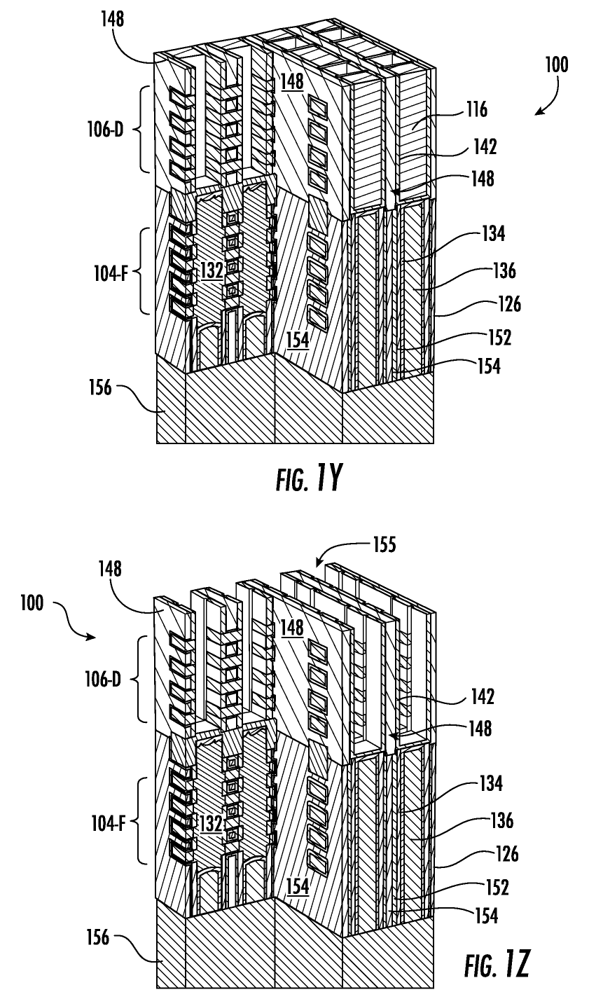

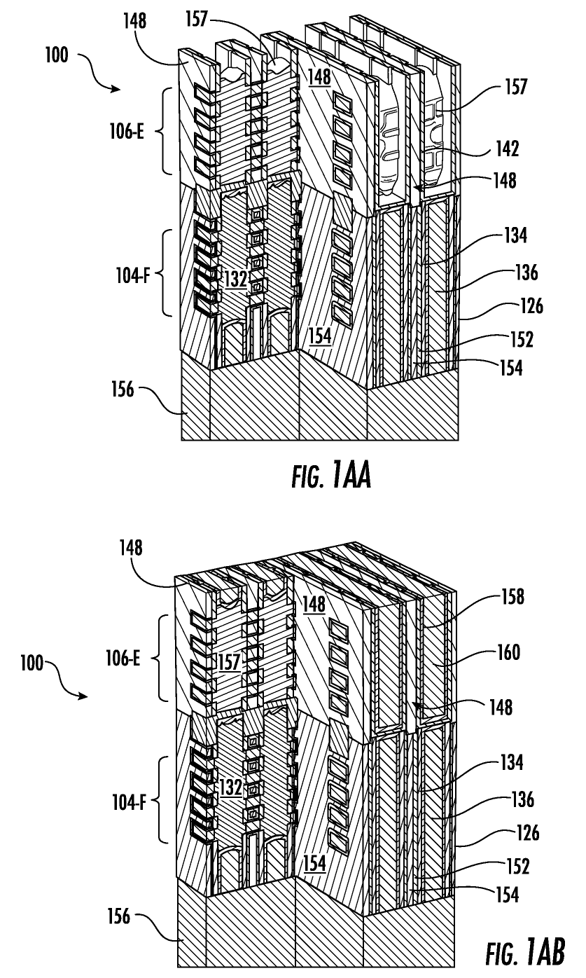

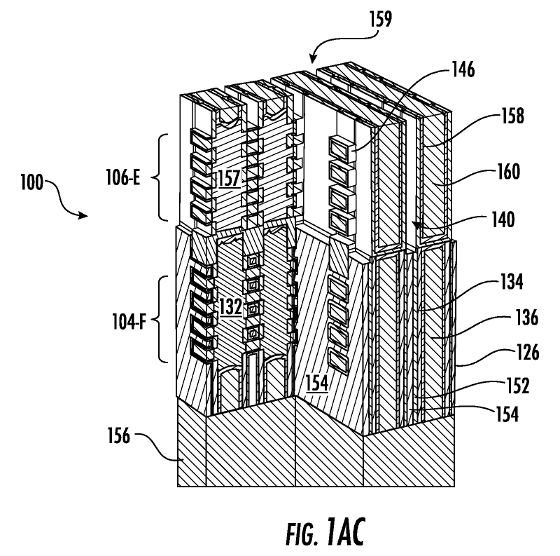

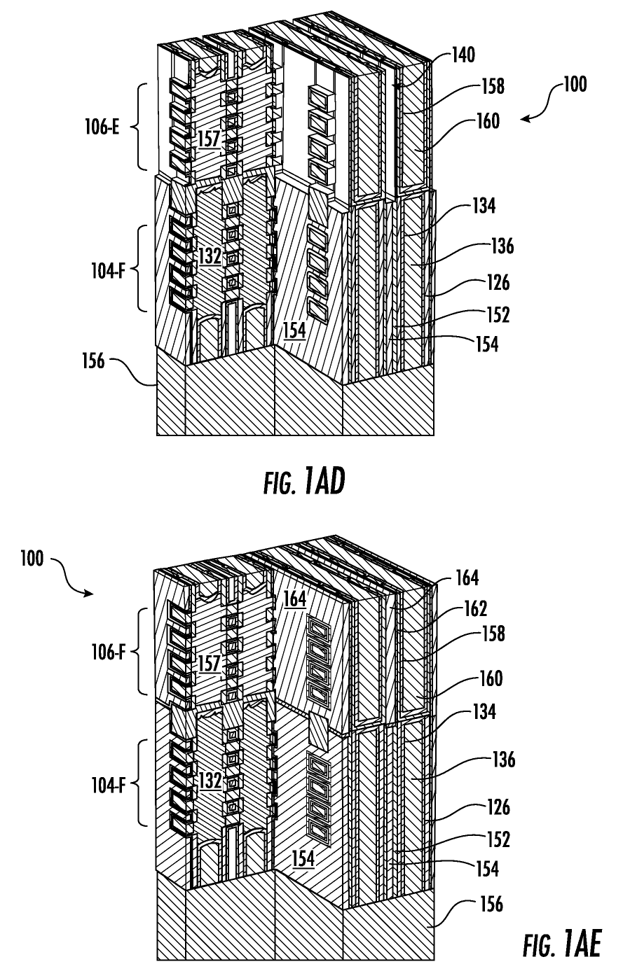

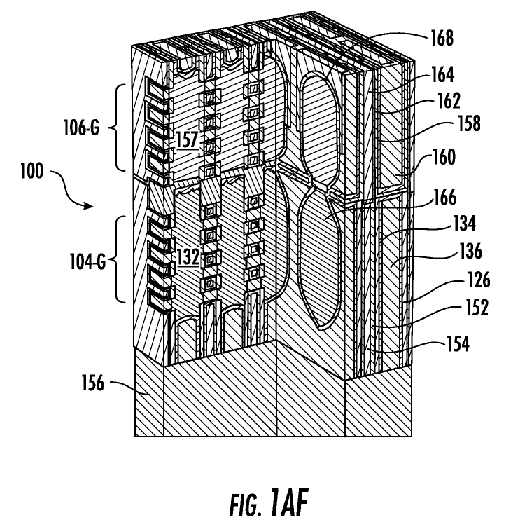

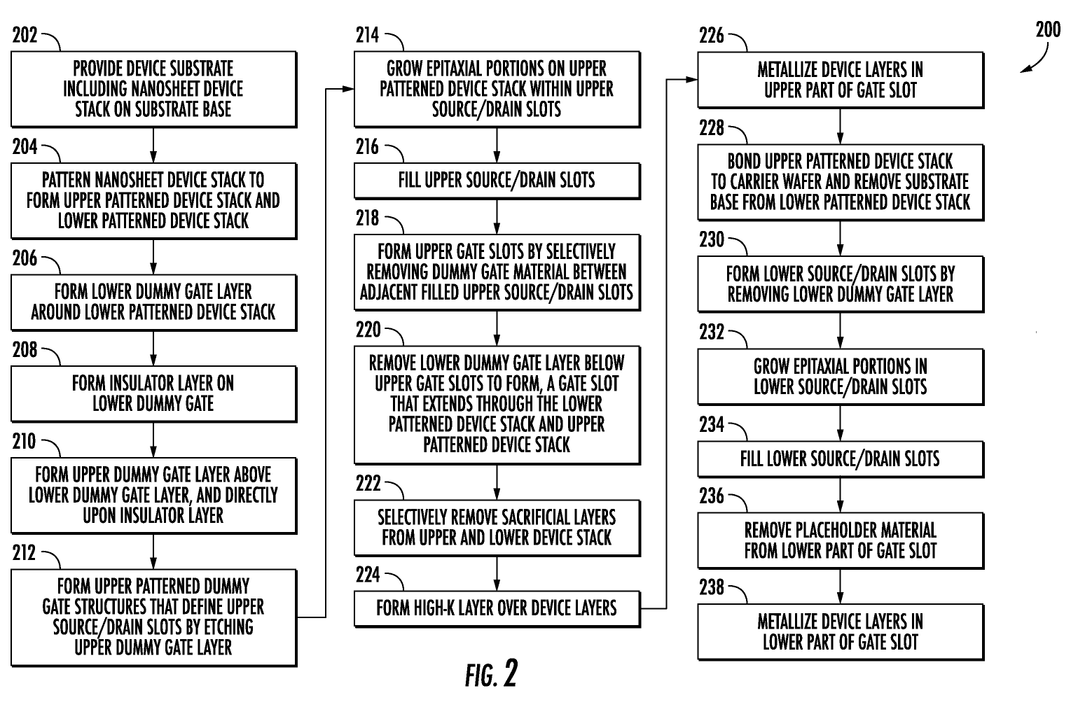

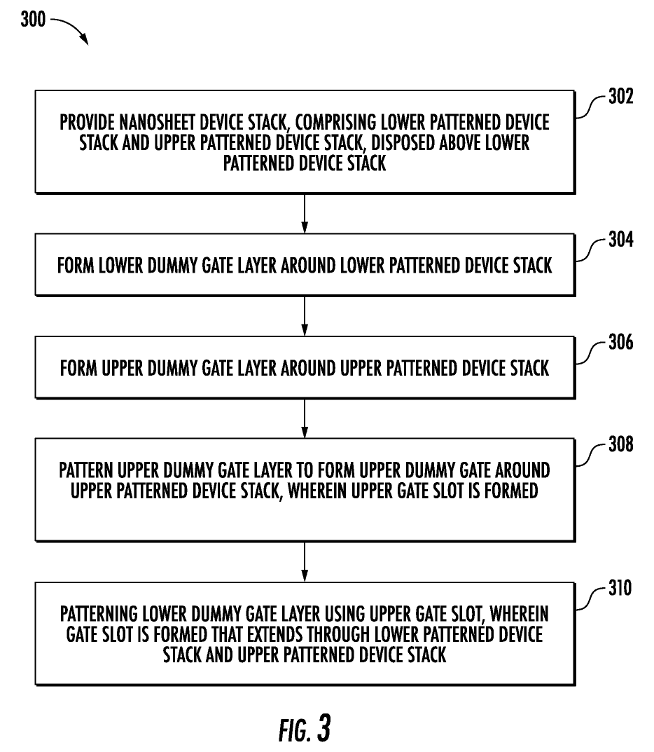

FIG. 3 presents another process flow 300, according to embodiments of the disclosure. At block 302, a nanosheet device stack is provided. The nanosheet device stack is formed of a lower patterned device stack and an upper patterned device stack that is disposed above the lower patterned device stack. Note that the lower device stack may be disposed on a substrate base, such as a monocrystalline semiconductor material.

At block 304, a lower dummy gate layer is formed around the lower patterned device stack. At block 306, an upper dummy gate layer is formed around the upper patterned device stack. At block 308, the upper dummy gate layer is patterned to form an upper dummy gate around the upper patterned device stack, wherein an upper gate slot is formed. At block 310, the lower dummy gate layer is patterned using the upper gate slot, wherein a gate slot is formed that extends through the lower patterned device stack and the upper patterned device stack.

The present embodiments provide numerous advantages over known approaches for synthesizing vertical stacked devices, such as CFET. In one advantage, the present embodiments reduce the aspect ratio of various structures for important processing stages, including the etching of dummy gate structures. Thus, the gate slot to form an upper transistor device is etched separately from the gate slot to form a lower transistor. Aspect ratio reduction is also accomplished for spacer RIE processes, recess etch, an inner spacer formation. Additionally, vertical patterning for NFET and PFET is eliminated. Notably, the present embodiments also provide that the upper and lower devices are processed in a self-aligned manner. Moreover, the requirement for fill processes, such as middle dielectric insulator (MDI), is less demanding. Furthermore, the process flow of the present embodiments places higher thermal budget operations at earlier stages, thus avoiding requirements for new silicide and contact materials. In addition to some of the specific advantages noted above, additional general advantages include the fact that the upper and lower devices are processed in a manner consistent with present day gate-all-around process capability. Also, the thermal budget for the present embodiments is the same as known GAA devices so that no new novel materials are required.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
providing a nanosheet device stack, comprising a lower patterned device stack and an upper patterned device stack, disposed above the lower patterned device stack, wherein the lower patterned device stack is disposed on a substrate base ;
forming a lower dummy gate layer around the lower patterned device stack, and forming a upper dummy gate layer around the upper patterned device stack;
patterning the upper dummy gate layer to form a upper dummy gate around the upper patterned device stack, wherein an upper gate slot is formed; and
patterning the lower dummy gate layer using the upper gate slot, wherein a gate slot is formed that extends through the lower patterned device stack and the upper patterned device stack.

2. The method of claim 1, further comprising, after the patterning the lower dummy gate layer:
forming an upper transistor device around the upper patterned device stack;
attaching a carrier substrate to a surface of the upper transistor device;
removing the substrate base from the lower patterned device stack; and
forming a second transistor device around the lower patterned device stack.

3. The method of claim 1, wherein an insulator layer is formed between the lower dummy gate layer and the upper dummy gate layer.

4. The method of claim 1, further comprising providing a hardmask layer on the upper dummy gate layer before the patterning the upper dummy gate layer.

5. The method of claim 2, further comprising forming a spacer in the gate slot adjacent to the lower patterned device stack, after formation of a source/drain in the upper patterned device stack.

6. The method of claim 5, wherein the nanosheet device stack comprises a plurality of first layers that alternate with a plurality of second layers, wherein the plurality of first layers and the plurality of second layers that are epitaxially grown upon each other.

7. The method of claim 6, wherein the first layers comprise monocrystalline silicon and the second layers comprise a monocrystalline silicon:germanium alloy, the method further comprising selectively removing the second layers after the forming the spacer in the gate slot.

8. The method of claim 7, further comprising filling the gate slot in a region adjacent to the lower patterned device stack, before completion of the forming the upper transistor device.

9. The method of claim 8, further comprising simultaneously forming a high-K layer in the gate slot adjacent to the lower patterned device stack and the upper patterned device stack before the filling the gate slot.

10. A method of forming a complementary field effect transistor, comprising:
providing a nanosheet device stack, comprising a lower patterned device stack and a upper patterned device stack, disposed on the lower patterned device stack, wherein the lower patterned device stack is disposed on a substrate base;
forming a lower dummy gate layer around the lower patterned device stack;
forming an insulator layer on the lower dummy gate layer;
forming a upper dummy gate layer on the insulator layer, wherein the upper dummy gate layer further extends around the upper patterned device stack;
etching the upper dummy gate layer to form a upper dummy gate around the upper patterned device stack, wherein an upper gate slot is formed; and
etching the lower dummy gate layer using the upper gate slot, wherein a gate slot is formed that extends through the upper patterned device stack and the lower patterned device stack.

11. The method of claim 10, further comprising, after the etching the lower dummy gate layer:
forming an upper transistor device, having a first polarity, around the upper patterned device stack;
attaching a carrier substrate to a surface of the upper transistor device;
removing the substrate base from the lower patterned device stack; and
forming a second transistor device, having a second polarity, opposite the first polarity, around the lower patterned device stack.

12. The method of claim 11, further comprising forming a spacer in the gate slot adjacent to the lower device stack, after formation of a upper source/drain in the upper patterned device stack.

13. The method of claim 12, wherein the nanosheet device stack comprises alternating first layers and second layers that are epitaxially grown upon each other.

14. The method of claim 13, wherein the first layers comprise monocrystalline silicon and the second layers comprise a monocrystalline silicon: germanium alloy, the method further comprising selectively removing the second layers after the forming the spacer in the gate slot.

15. The method of claim 14, further comprising filling the gate slot in a region adjacent to the lower patterned device stack, before completion of the forming the upper transistor device.

16. The method of claim 15, further comprising simultaneously forming a high-K layer in the gate slot adjacent to the lower patterned device stack and the upper patterned device stack before the filling the gate slot.
